(19) United States
(12) Patent Application Publication
(10) Pub. No.: US 2007/0279083 A1
(43) Pub. Date: Dec. 6, 2007

(54) Buffer circuit with output signal slope control means

(75) Inventors: Thierry Padilla, Saint-Martin D'Heres (FR); Mikael Rien, Crolles (FR)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: STMicroelectronics S.A., Montrouge (FR)

(21) Appl. No.: 11/787,192

(22) Filed: Apr. 12, 2007

(30) Foreign Application Priority Data
Apr. 13, 2006 (FR) 060338

(51) Int. Cl. H03K 19/003

(52) U.S. Cl. 326/29

(57) ABSTRACT

A buffer circuit for transmission of logical signals includes a first buffer and second buffer. The first buffer supplies logical signals to the output buffer which is connected in series with the first buffer to produce output logical signals. A slope of the logical signals produced at the output of the output buffer is controlled in order to adapt the signal transmission speed. The first buffer and output buffer preferably are logic gates (such as inverters) made using the CML technology. The slope of the output signal is controlled using a slope control module which applies a logical signal which programs a resistance value of a pair of variable output resistances of the CML logic gate which forms the first buffer.

### PRIORITY CLAIM

This application claims priority from French Application for Patent No. 06 03308 filed Apr. 13, 2006, the disclosure of which is hereby incorporated by reference.

### BACKGROUND OF THE INVENTION

1. Technical Field of the Invention

The present invention relates to data transfers on high speed serial links between electronic data transmission modules and electronic data reception modules. In particular, it relates to a buffer circuit for transmitting logical signals comprising means of controlling the slope of the logical signal produced at the output.

2. Description of Related Art

In integrated circuits comprising high speed serial data transmission links, it frequently arises that logical signals representing data to be transmitted are applied to buffer circuits formatting these signals and implementing impedance matching at the input to the integrated circuits to which they are addressed.

For example, FIG. 1 represents a conventional embodiment of a buffer circuit 10 using an inverter gate 20. The inverter gate 20 comprises a PMOS transistor in series with an NMOS transistor, the source of the PMOS transistor being biased by a power supply voltage Vcc and the source of the NMOS transistor being connected to the ground. The buffer circuit 10 receives a logical IN signal at the input and produces an output signal OUT.

The structure of the buffer circuit must be defined so as to take account of the data transfer standard to which it will be applied, particularly concerning time specifications of the transmitted signals.

In this description, it is assumed that the buffer circuit 10 is arranged in an integrated circuit comprising means of transmitting data and for example designed for transmission of high speed serial data between a computer processor and a hard disk controller using the S-ATA (Serial Advanced Technology Attachment) serial link standard.

At the moment, this standard covers two generations, namely the S-ATA Gen1 and S-ATA Gen2 respectively and a third generation is currently being developed, each of them defining specification constraints to be taken into account for the output signal from the data transmission circuit. These constraints are presented in the following table:

| | | S-ATA Gen1 | S-ATA Gen2 |
|---|---|---|---|
| Rise and fall time of the | Min | 100 ps | 67 ps |
| transmission circuit | Max | 273 ps | 136 ps |
| output signal (20%-80%) | | | |

Therefore, specification constraints for the S-ATA Gen1 standard make it necessary for the output signal produced by the buffer circuit of the data transmission circuit to have a signal rise and fall time equal to between 100 ps (picoseconds) and 273 ps. Standard S-ATA Gen2 imposes a rise and fall time of the output signal equal to between 67 ps and 136 ps.

These times are typically measured between two points corresponding to 20% and 80% respectively of the total amplitude of the output signal. To help understand the concept, FIG. 2 illustrates the meaning of the rise time and the fall time as specified by the standard, on a rising front and a falling front respectively of the output signal shown diagrammatically.

Consequently, the design of a data transmission circuit that can be compatible with two generations of the S-ATA standard according to the above example, states that the rise and fall times of the output signal produced by the output butffer circuit are necessarily within the range common to the two generations, namely between 100 ps and 136 ps. But the time range common to the two generations in the standard is too narrow, making it impossible to design a buffer circuit giving such rise and fall times of the output signal compatible with the two generations in the standard, taking account of dispersions inherent to the circuit.

As can be seen in FIG. 2, the rise and fall times of the buffer circuit output signal depend on the slope of the signal. When the slope is steeper, the rise and fall times are faster (shorter). Conversely, when the slope is less steep, the rise and fall times are slower (longer). Starting from these considerations, rather than designing output buffer circuits for which the architecture is specifically designed to adapt to time constraints according to a given standard to the detriment of compatibility with other standards, it has been envisaged to use architectures making it possible to modify the slope of the output signal to make it possible to satisfy different time constraints depending on the standards.

Solutions based on CMOS technological gates like those illustrated in FIG. 1 have been developed, by which it is possible to modify the slope of the output signal. Their operating principle is illustrated diagrammatically in FIG. 3 and consists of adding delays into the signal propagation on the input side of the buffer. These delays are added incrementally, in other words more or less elementary delays are added to slow down more or less the signal at the output from the buffer circuit. This is done using a plurality of CMOS output buffers 10 in parallel and each of the branches in parallel receives its own control signal, IN to IN-Dn respectively, offset in time with a given delay that is incremented for each branch (from 1 to n elementary delays). Thus, the rise or fall time of the signal can be modulated by adding one branch to the others or removing one branch from the others for the composition of the resultant output signal OUT during the transition phase of this signal.

However, this solution is not satisfactory. Firstly, the output signal thus generated comprises discontinuities. Furthermore, the CMOS architecture described above has disadvantages in terms of noise and data integrity. Furthermore, this architecture of the output buffer circuit is not very flexible and it is limited to adapt to some standards. A wide range of programming of the slope of the output signal would require an increasingly large number of programming bits, which would be restrictive firstly in terms of the complexity of the circuit, and secondly the size occupied.

Therefore, a need exists in the art to overcome these disadvantages by proposing a new architecture of the output buffer circuit that enables configuration of the slope of the output signal to easily adapt to a large number of high speed serial data transmission standards imposing different ranges of the output signal rise and fall times.

### SUMMARY OF THE INVENTION

With this objective in mind, a buffer circuit for transmission of logical signals comprises a first buffer to supply said logical signals to an output buffer connected in series with the first buffer to produce said signals to the output of the buffer circuit, and means of controlling the slope of the logical signals produced at the output in order to adapt the signal transmission speed. Said first buffer and said output buffer comprise a logical gate made using the CML technology. Said means of controlling the slope of the output signal comprises a slope control module designed to apply a logical signal programming the value of a pair of variable output resistances of the CML gate forming said first buffer.

According to one embodiment, the CML gate forming the first buffer comprises a pair of input transistors for which the drains connected to a high power supply potential through a variable output resistance corresponding to the pair of variable output resistances supply logical signals to the output buffer, and a variable current source connected between the ground and the corresponding sources of the pair of input transistors, said variable current source being programmed by the programming signal produced by the slope control module.

According to one embodiment, the CML gate forming the output buffer comprises a pair of input transistors driven by logical signals provided at the output from the first buffer, the drains of which are connected to a high power supply potential through two corresponding output resistances, and a current source connected between the ground and the corresponding sources in the pair of input transistors, the slope of the logical signals produced at the output from the buffer being governed by the rate of charge and discharge of the gate-source capacitance of the input transistors in the CML gate forming the output buffer.

Advantageously, the programmable value of the pair of variable output resistances of the CML gate forming the first buffer, programmed through the logical programming signal, is used to define the charge and discharge rate of the gate-source capacitance of the input transistors of the CML gate forming the output buffer.

Preferably, each variable resistance in the pair of variable output resistances in the CML gate forming the first buffer comprises a plurality of resistances connected in parallel and means controlled by the programming signal of adding or removing resistances among said plurality of resistances in parallel, so as to program a global value of the variable resistance.

Advantageously, the initial global value programmed for the pair of variable output resistances in the CML gate forming the first buffer is the value corresponding to the set of the plurality of resistances taken in parallel, so as to program the steepest slope for the output signals.

Preferably, the variable current source of the CML gate forming the first buffer comprises a plurality of current sources connected in parallel and means controlled by the programming signal of adding or removing current sources among said plurality of current sources in parallel, so as to program a global value of the variable current source.

Advantageously, the value of the variable current source is programmed such that the product of the value of the variable output resistance of the CML gate forming the first buffer and the value of the variable current source of the CML gate forming the first buffer remains constant, regardless of the programming of the value of the variable output resistance.

In one example application, the buffer circuit is adapted to transmission of high speed serial data for the different generations in the S-ATA standard.

An integrated circuit comprises a buffer circuit like that described above.

In another embodiment, a buffer circuit comprises a first buffer receiving an input digital signal and generating an intermediate digital signal, the first buffer including a variable resistance coupled to an output terminal from which the intermediate digital signal is generated; a second buffer receiving the intermediate digital signal and generating an output digital signal; wherein the variable resistance of the first buffer is varied in response to a received slope control signal so as to cause a change in a time constant which would correspondingly vary a slope of the generated output digital signal.

### BRIEF DESCRIPTION OF THE DRAWINGS

Other characteristics and advantages will become clearer after reading the following description given as an illustrative and non-limitative example with reference to the appended figures, wherein:

FIG. 1, described above, represents a classical buffer circuit;

FIG. 2, described above, illustrates constraints to be taken into account for the output signal from the buffer circuit, related to time specifications imposed by the standard;

FIG. 3 illustrates a known architecture of the buffer circuit using the CMOS technology, enabling control of the slope of the output signal;

FIG. 4 illustrates the structure of a CML gate on which the architecture of a buffer circuit is based;

FIG. 5 illustrates the functional architecture of a buffer circuit used to control the slope of the circuit output signal;

FIG. 6 illustrates the operating principle for controlling the slope of the buffer circuit output signal; and

FIG. 7 illustrates the logical structure of the input buffer described in FIG. 5 used to control the slope at the output signal.

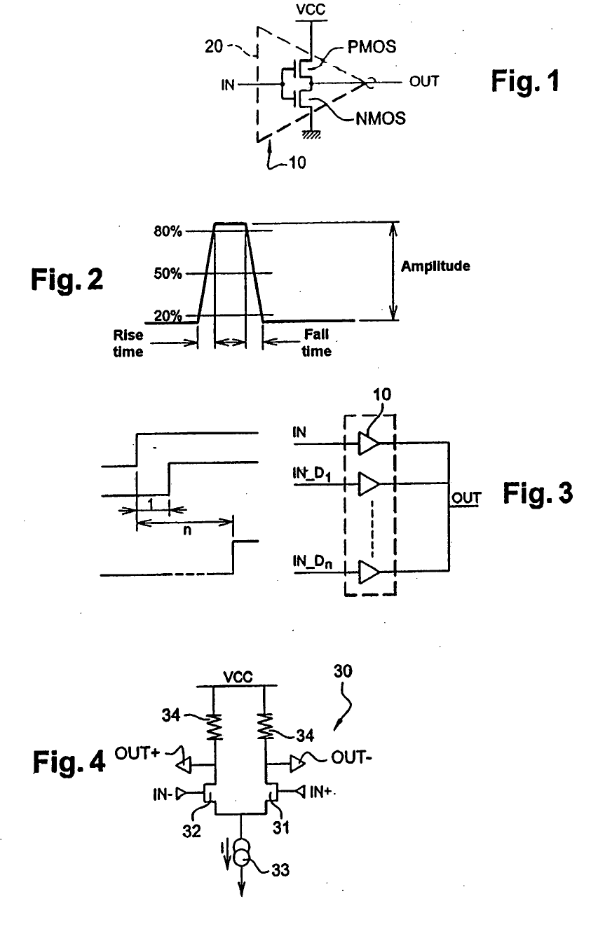

### DETAILED DESCRIPTION OF THE DRAWINGS

The architecture of the buffer circuit is based on the use of CML (Current Mode Logic) gates, the structure of which is shown in FIG. 4.

A CML gate 30 comprises a differential pair of input transistors 31, 32 of the nMOS type, the drains of which are connected to a high power supply potential Vcc through two corresponding output resistances 34 with value R. The CML gate also comprises a current source 33 outputting a current I and connected between the ground and the corresponding sources of the differential pair of transistors 31, 32.

Differential input signals IN+ and IN− are applied to the gates of transistors 31, 32 respectively of the pair of input transistors to the CML gate. The OUT− and OUT+ outputs from the CML gate are taken at the corresponding drains of transistors 31 and 32, and output signals in phase opposition.

Thus, the current source 33 of the CML gate is designed to be applied to the two switches formed by the pair of transistors 31, 32 controlled in phase opposition, so that the output resistance 34 can be loaded in turn. Either the switch is open (input signal in the low state applied to the transistor gate) and in this case the signal Vcc occurs on the corresponding output, or the switch is closed (input signal in the high state applied to the transistor gate) and in this case the Vcc-RI signal is applied to the corresponding output. Therefore, the variation in the amplitude of the voltage between the two levels reached is equal to RI.

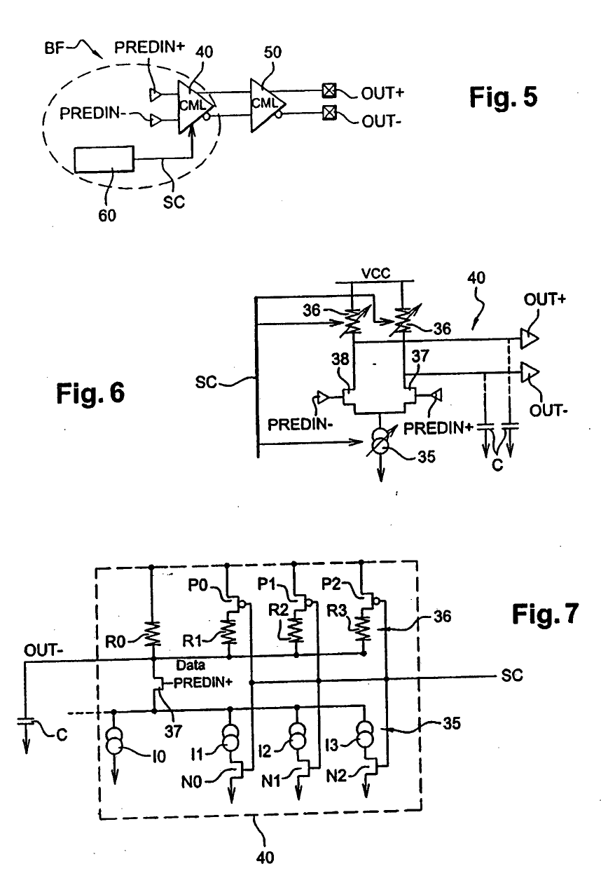

FIG. 5 illustrates the functional architecture of a buffer circuit BF. The buffer circuit BF comprises two logical gates CML in series, 40 and 50, forming the input stage and the output stage respectively. Each logical gate 40 and 50 is of the type described with reference to FIG. 4. The buffer circuit BF receives the PREDIN+ and PREDIN− signals applied to the input of gate 40, and produces the OUT+ and OUT− signals output by the gate 50 at the output.

Therefore, the CML gate 50, the structure of which is absolutely identical to the gate described in FIG. 4, acts as an output buffer adapted to transmit final signals to the load external to the circuit. The gate 40 thus forms a first buffer, the role of which is to prepare output signals to be transmitted to relieve the output buffer.

The characteristic of the signals at the output from the buffer circuit BF is that their slope can be controlled. This is done by providing the buffer circuit BF with a slope control module 60, adapted to apply a logical programming signal SC to the first buffer 40 level. Thus, the slope of the output signal from the buffer circuit is controlled only at the first buffer 40 level, as will be described more precisely below with reference to FIG. 6.

Therefore, the structure of the first buffer 40 is based on the structure of a CML gate like that described in FIG. 4, but nevertheless is different in that it has a variable current source 35 and a pair of variable output resistances 36, for which the corresponding values Ivar and Rvar are defined as a function of the programming signal SC output by the slope control module 60. The input signals PREDIN+ and PREDIN− are applied at the gates of transistors 37 and 38 respectively in the pair of input transistors to the CML gate forming switches.

The output buffer 50 then represents a constant load at the output from the first buffer 40, that can be symbolized on each output line OUT+ and OUT− by two capacitances C, each representing the gate-source capacitance of the input transistors 31, 32 of the CML gate of the output buffer. Thus, in an intermediate phase in which the output signals OUT+ and OUT− from the gate 40 are between the high and low levels, namely Vcc and Vcc-Rvar.Ivar respectively defining the gate output voltage excursion, the OUT+ and OUT− signals will charge or discharge the capacitances C.

Therefore, the slope of the signal on each output line of the buffer 40, between the two high and low levels defining the rise and fall time of the output signal, is governed by the rate of charging and discharging the capacitance C, characterized by the time constant Rvar.C. Since the output buffer represents a constant load for the first buffer, changing the value Rvar of the output resistance 36 of the CML gate forming the first buffer 40 will provide a means of modifying this time constant and therefore increasing or reducing the charging rate of the capacitance C, thus controlling the slope of the output signal.

This mechanism is governed by the programming signal SC, which programs the value of the pair of variable output resistances 36 of the CML gate forming the first buffer 40, to obtain the slope required for the buffer output signals 40. The signal SC can also be used to program the value of the variable current source 35 of the first buffer 40. In this case the objective is to be able to keep the voltage excursion constant at the output from the first buffer 40, regardless of the programming of the value of the variable output resistance. As already mentioned, this voltage excursion is equal to the current value produced by the current source multiplied by the value of the output resistance of the CML gate. Thus, a change to the value of the resistance for the purposes of controlling the slope of the output signal must necessarily be compensated by an appropriate adaptation of the value of the current produced by the current source, to keep this voltage excursion constant.

The output signals from the first buffer 40 will then be transferred to the output of the output buffer 50 of the buffer circuit BF, with the same time characteristics concerning their rise and fall times as were defined by the control mechanism acting as described above on the first buffer 40. The output signals produced by the first buffer 40 will more precisely control the switches formed by the pair of input transistors 31, 32 of the CML gate forming the output buffer 50.

Therefore, the rise and fall time characteristics of the output signals from the output buffer 50 will be dictated by the rise and fall times of the first stage formed by the buffer 40, for which the intrinsic time characteristics are dominant. The charge/discharge time intrinsic to the output stage 50 is very much less than the corresponding time for the first buffer 40.

FIG. 7 now illustrates an example embodiment of the logical structure of the first buffer 40 in more detail, to control operation of the slope control mechanism as it has just been described with reference to FIG. 6. FIG. 7 actually illustrates only half of the structure of the first buffer 40. In other words, a single phase of the output signal is represented, for example the OUT− phase.

Therefore, for the phase described, there is the variable current source 35 of the CML gate common to the two phases, designed to be applied to the switch 37, so as to load a resistance in the pair of variable output resistances 36 according to the applied signal PREDIN+.

The structure is absolutely symmetrical for the other phase of the output signal OUT+, not shown.

According to the example, the variable output resistance 36 shown is composed of four branches in parallel each comprising a resistance R0 to R3. Means are provided to increase or reduce the number of branches placed in parallel such that the value of the variable resistance 36 is modulated. More precisely, branches R1 to R3 each comprise a P type switch transistor P0 to P2 respectively, controlled by the logical signal SC. Thus, the state of the switches P0 to P2 is controlled in the closed or open state depending on the value of the signal SC, consequently so that the corresponding resistive branch can be added or removed and therefore the value of the global variable resistance 36 can be modulated.

According to the example in FIG. 7, eight different values of the output resistance 36 of the buffer 40, and therefore eight different values of the rise and fall time of the output signal, could be programmed depending on the needs for adaptation to different transmission standards.

At the same time, the value produced by the variable current source 35 is controlled so that a constant output voltage excursion can be kept depending on the value of the programmed variable resistance 36.

To achieve this, the variable current source comprises four branches in parallel, each comprising a current source I0 to I3 . Each branch I1 to I3 also comprises an N type switch transistor N0 to N2 respectively controlled by the logical signal SC used to add or remove the corresponding current source branch to thus increase or reduce the global value of the current supplied by the variable current source 35 accordingly.

More precisely, the switch transistors N0 to N2 are controlled by the logical signal SC in a complementary manner to the transistors P0 to P2. Thus, when a control signal in the low (high) state is applied to the gate of the transistor P0, a complementary control signal in the high (low) state is applied simultaneously on the gate of the switch transistor N0. The same is true for other pairs of switch transistors P1/N1 and P2/N2. Due to this complementary control of switch transistors of the variable resistance and the variable current source, when a branch is added (or removed) at the variable resistance 36, a corresponding branch is also added (or removed) at the variable current source.

When a resistive branch is added in parallel at the variable resistance 36, the global value of the resistance is reduced, which is compensated by the fact that a branch of the current source is added simultaneously in parallel, to increase the global value of the current output by the variable source accordingly. Also, when a resistive branch in parallel with the variable resistance 36 is removed, the global value of the resistance is correspondingly increased, which is compensated by the fact that a branch of the current source in parallel is simultaneously removed, so that the global value of the current output by the variable source is reduced accordingly.

In this way, the product of the global value Rvar of the variable resistance 36 and the global value Ivar of the variable current source 35 remains constant, however the time constant Rvar.C defining the rise and fall time characteristics of the buffer output circuit 40 may be programmed by modulating the value of the resistance Rvar, thus making it possible to adapt the buffer circuit to different transmission standards defining different time specifications for the output signals.

The number of branches in parallel at the variable resistance and the variable current source and therefore the number of bits for programming the output signal slope making up the signal SC for controlling the simultaneous addition and removal of these branches, is given herein simply as an example.

The slope control command SC is made statically and is defined before the beginning of the signal transmission. In other words, there is no modification to the programming bits making up the command SC during signal transitions. The result is an output signal with no discontinuities.

The fastest data transmission standard dictates the design constraints for the buffer circuit, in other words it imposes the shortest rise and fall times. To achieve this, the signal SC is programmed so that all resistances R0 to R3 according to the example are placed in parallel, to obtain the lowest possible global initial value Rvar of the variable resistance 36 and therefore the lowest time constant Rvar.C, corresponding to the highest slope allowed by the buffer circuit architecture. The proposed architecture then makes it easy to adapt to standards imposing slower time specifications later on, by programming the removal of one or several resistances in parallel, thus increasing the global value of the variable resistance, that can give a higher constant value of the time constant Rvar.C and therefore slow down the signal to adapt to slower standards.

Therefore, the architecture of the buffer circuit is particularly advantageous in that it can provide a buffer circuit in which the means of controlling the slope of the output signal can easily be configured, to make the circuit compatible with several generations of data transmission standards, particularly for transmission of serial data at high speed.

The usefulness of the slope control on output signals has thus been illustrated above with reference to standard S-ATA, but the invention is not limited to this standard and in general it covers any application for the transmission of differential data in serial link.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A buffer circuit for transmission of logical signals, comprising:
a first buffer to supply said logical signals;
an output buffer connected in series with the first buffer to produce said logical signals at the output from the buffer circuit; and
means for controlling a slope of the logical signals produced at the output in order to adapt a signal transmission speed;
wherein said first buffer and said output buffer each comprise a logical gate made using the CML technology;
wherein said means for controlling the slope of the output signal comprises a slope control module which applies a logical signal for programming the value of a pair of variable output resistances of a CML gate which forms said first buffer.

2. The buffer circuit according to claim 1, wherein the CML gate forming the first buffer comprises:
a pair of input transistors whose drains are connected to a high power supply potential through a variable output resistance corresponding to the pair of variable output resistances which supply the logical signals to the output buffer; and
a variable current source connected between ground and the corresponding sources of the pair of input transistors, said variable current source being programmed by the programming signal produced by the slope control module.

3. The buffer circuit according to claim 1, wherein the CML gate forming the output buffer comprises a pair of input transistors driven by logical signals provided at the output from the first buffer, wherein drains of the input transistors are connected to a high power supply potential through two corresponding output resistances, and a current source is connected between ground and corresponding sources of the pair of input transistors, the slope of the logical signals produced at the output from the buffer being governed by the rate of charge and discharge of a gate-source capacitance of the input transistors in the CML gate forming the output buffer.

4. The buffer circuit according to claim 3, wherein the programmable value of the pair of variable output resistances of the CML gate forming the first buffer, which are programmed through the logical programming signal, is used to define the charge and discharge rate of the gate-source capacitance of the input transistors of the CML gate forming the output buffer.

5. The buffer circuit according to claim 1, wherein each variable resistance in the pair of variable output resistances in the CML gate forming the first buffer comprises a plurality of resistances connected in parallel and means controlled by the programming signal for adding or removing resistances among said plurality of resistances in parallel, so as to program a global value of the variable resistance.

6. The buffer circuit according to claim 5, wherein the initial global value programmed for the pair of variable output resistances in the CML gate forming the first buffer is the value corresponding to the set of the plurality of resistances taken in parallel, so as to program the steepest slope for the output signals.

7. The buffer circuit according to claim 2, wherein the variable current source of the CML gate forming the first buffer comprises a plurality of current sources connected in parallel and means controlled by the programming signal for adding or removing current sources among said plurality of current sources in parallel, so as to program a global value of the variable current source.

8. The buffer circuit according to claim 7, wherein the value of the variable current source is programmed such that the product of the value of the variable output resistance of the CML gate forming the first buffer and the value of the variable current source of the CML gate forming the first buffer remains constant, regardless of the programming of the value of the variable output resistance.

9. The buffer circuit according to claim 1, wherein the buffer circuit is controllable to adapt to transmission of high speed serial data for at least a first S-ATA rate and a second, different, S-ATA rate.

10. The buffer circuit of claim 1 wherein the buffer circuit is implemented as an integrated circuit.

11. A buffer circuit, comprising:
a first buffer receiving an input digital signal and generating an intermediate digital signal, the first buffer including a variable resistance coupled to an output terminal from which the intermediate digital signal is generated;
a second buffer receiving the intermediate digital signal and generating an output digital signal;
wherein the variable resistance of the first buffer is varied in response to a received slope control signal so as to cause a change in a time constant which would correspondingly vary a slope of the generated output digital signal.

12. The buffer circuit of claim 11 wherein the first and second buffers are differential circuits.

13. The buffer circuit of claim 11 wherein the first buffer comprises:
a transistor have a gate and a source/drain circuit, wherein the input digital signal is received by the gate; and
wherein the variable resistance is coupled to the source/drain circuit of the transistor.

14. The buffer circuit of claim 13 further comprising a controllable current source coupled to the source/drain circuit of the transistor, a current of the controllable current source being variable in response to the received slope control signal.

15. The buffer circuit according to claim 11, wherein the buffer circuit is controllable through the slope control signal to adapt to transmission of high speed serial data for at least a first S-ATA rate and a second, different, S-ATA rate.

16. The buffer circuit of claim 11 wherein the time constant is dependent on a set value of the variable resistance and a gate-source capacitance of an input transistor within the second buffer.
